(19) United States
(12) Patent Application Publication
(10) Pub. No.: US 2025/0263584 A1
(43) Pub. Date: Aug. 21, 2025

(54) POLISHING COMPOSITION AND POLISHING METHOD

(71) Applicant: FUJIMI INCORPORATED, Kiyosu-shi (JP)

(72) Inventors: Ryo Wakabayashi, Kiyosu-shi (JP); Daisuke Yasui, Kiyosu-shi (JP); Masayuki Serikawa, Kiyosu-shi (JP)

(73) Assignee: FUJIMI INCORPORATED, Kiyosu-shi (JP)

(21) Appl. No.: 19/053,065

(22) Filed: Feb. 13, 2025

(30) Foreign Application Priority Data
Feb. 16, 2024 (JP) 2024-022137

(51) Int. Cl. C09G 1/02

(52) U.S. Cl. CPC C09G 1/02

(57) ABSTRACT

The present disclosure provides a means capable of reducing defects on a surface of a resin material after polishing while maintaining a high polishing removal rate in polishing of a polishing target containing a resin material.

The present disclosure is a polishing composition used for polishing a polishing target containing a resin material, the polishing composition containing water and alumina particles, in which, in the alumina particles, when a particle size at which a cumulative frequency from a small particle size side is 2% in a volume-based particle size distribution is denoted by D₂, a particle size at which a cumulative frequency from a small particle size side is 50% in a volume-based particle size distribution is denoted by D₅₀, a particle size at which a cumulative frequency from a small particle size side is 98% in a volume-based particle size distribution is denoted by D₉₈, a BET specific surface area is denoted by SA, and a theoretical specific surface area calculated from the D₅₀ is denoted by SA′, a degree of deformity N represented by formula (1) below satisfies a relationship of formula (2) below, and a degree of distortion S represented by formula (3) below satisfies a relationship of formula (4) below.

$$Degree of deformity N = \frac{SA}{{SA}^{′}} \qquad ( 1 )$$

$$2 \leq N \leq 6 \qquad ( 2 )$$

$$Degree of distortion S = \frac{( {D}_{50} / {D}_{2} )}{( {D}_{98} / {D}_{50} )} \qquad ( 3 )$$

$$0.5 \leq S \leq 0.80 \qquad ( 4 )$$

### CROSS-REFERENCE TO RELATED APPLICATION

The present application is based on Japanese Patent Application No. 2024-022137 filed on Feb. 16, 2024, the disclosure content of which is incorporated herein by reference in its entirety.

### BACKGROUND

### 1. Technical Field

The present disclosure relates to a polishing composition and a polishing method.

### 2. Description of Related Arts

In the semiconductor industry, a flattening technique is usually used to increase the flatness of a surface of a semiconductor substrate (for example, a wafer). Chemical mechanical polishing (CMP) is one of the commonly used flattening techniques. The chemical mechanical polishing technique is a method for flattening the surface of a polishing target (object to be polished) such as a semiconductor substrate using a polishing composition containing abrasive grains of silica, alumina, ceria, or the like, an anticorrosive agent, a surfactant, and the like.

Furthermore, a substrate containing a resin material (also referred to as a “resin-containing substrate” in the present specification) has also become widespread. Therefore, the need for a polishing composition applied to polish a resin-containing substrate is gradually increasing.

For example, JP 2005-268666 A (corresponding to US 2005/204638 A) discloses a chemical mechanical polishing composition containing alumina, a complexing agent, and an oxidizing agent. The chemical mechanical polishing composition of JP 2005-268666 A (corresponding to US 2005/204638 A) can be applied to perform chemical mechanical polishing on a resin layer and a conductor layer containing a metal.

### SUMMARY

However, there has been conventionally no polishing composition capable of reducing defects on a surface of a resin material after polishing while polishing a substrate containing a resin material at a high speed.

Therefore, an object of the present disclosure is to provide a means capable of reducing defects on a surface of a resin material after polishing while maintaining a high polishing removal rate in polishing of a polishing target containing a resin material.

The inventors of the present disclosure have conducted intensive studies in order to solve the above problem. As a result, the inventors of the present disclosure have found that the above problem can be solved by the following means, and have completed the invention of the present disclosure.

That is, the above problem of the present disclosure can be solved by the following means:

A polishing composition used for polishing a polishing target containing a resin material, the polishing composition containing water and alumina particles, in which, in the alumina particles, when a particle size at which a cumulative frequency from a small particle size side is 2% in a volume-based particle size distribution is denoted by D₂, a particle size at which a cumulative frequency from a small particle size side is 50% in a volume-based particle size distribution is denoted by D₅₀, a particle size at which a cumulative frequency from a small particle size side is 98% in a volume-based particle size distribution is denoted by D₉₈, a BET specific surface area is denoted by SA, and a theoretical specific surface area calculated from the D₅₀ is denoted by SA′, a degree of deformity N represented by formula (1) below satisfies a relationship of formula (2) below, and a degree of distortion S represented by formula (3) below satisfies a relationship of formula (4) below.

$$\begin{matrix}[ Math . 1 ] & \\ Degree of deformity N = \frac{SA}{{SA}^{′}} & ( 1 )\end{matrix}$$

$$2 \leq N \leq 6 \qquad ( 2 )$$

$$Degree of distortion S = \frac{( {D}_{50} / {D}_{2} )}{( {D}_{98} / {D}_{50} )} \qquad ( 3 )$$

$$0.5 \leq S \leq 0.80 \qquad ( 4 )$$

### DETAILED DESCRIPTION

Hereinafter, embodiments of the present disclosure will be described. The embodiments illustrated herein are illustrated to embody the technical idea of the present disclosure, and do not limit the present disclosure. Therefore, other feasible embodiments, usage methods, operation techniques, and the like that can be conceived by those skilled in the art and the like are all included in the scope and gist of the present disclosure and included in the invention described in the claims and the scope of equivalents thereof without departing from the gist of the present disclosure. The embodiments described in the present specification can be arbitrarily combined to form other embodiments.

In the present specification, unless otherwise specified, operations and measurements of physical properties and the like are performed under conditions of room temperature (within a range of 20° C. or higher and 25° C. or lower)/relative humidity of 40% RH or more and 50% RH or less.

A first embodiment of the present disclosure is a polishing composition used for polishing a polishing target containing a resin material, the polishing composition containing alumina particles and water, in which, in the alumina particles, when a particle size at which a cumulative frequency from a small particle size side is 2% in a volume-based particle size distribution is denoted by D₂, a particle size at which a cumulative frequency from a small particle size side is 50% in a volume-based particle size distribution is denoted by D₅₀, a particle size at which a cumulative frequency from a small particle size side is 98% in a volume-based particle size distribution is denoted by D₉₈, a BET specific surface area is denoted by SA, and a theoretical specific surface area calculated from the D₅₀ is denoted by SA′, a degree of deformity N represented by formula (1) below satisfies a relationship of formula (2) below, and a degree of distortion S represented by formula (3) below satisfies a relationship of formula (4) below.

$$\begin{matrix}[ Math . 2 ] & \\ Degree of deformity N = \frac{SA}{{SA}^{′}} & ( 1 )\end{matrix}$$

$$2 \leq N \leq 6 \qquad ( 2 )$$

$$Degree of distortion S = \frac{( {D}_{50} / {D}_{2} )}{( {D}_{98} / {D}_{50} )} \qquad ( 3 )$$

$$0.5 \leq S \leq 0.80 \qquad ( 4 )$$

The polishing composition of the present embodiment having a configuration as described above can reduce defects on a surface of a resin material after polishing while maintaining a high polishing removal rate in polishing of a polishing target containing a resin material.

Hereinafter, the present disclosure will be described in detail. In the present specification, the “polishing removal rate” is synonymous with “polishing speed” and “polishing rate”.

### Polishing Target

The polishing target applied to the polishing composition according to some embodiments of the present disclosure contains a resin material. The polishing composition according to the present disclosure is particularly suitable for polishing a substrate including a patterned structure formed of a material containing a resin material, and the technical effect of the present disclosure is fully exhibited when such a substrate is polished.

The resin material contained in the polishing target is not particularly limited, and examples thereof include polyethylene terephthalate (PET), polybenzoxazole (PBO), polybutylene terephthalate (PBT), polyimide (PI), polyamide (PA), an epoxy resin, a urethane acrylate resin, an unsaturated polyester resin, a phenol resin, a polynorbornene resin, polyacetal (POM), polycarbonate (PC), modified polyphenylene ether (m-PPE), ultra-high molecular weight polyethylene (UHMWPE), syndiotactic polystyrene (SPS), amorphous polyarylate (PAR), polysulfone (PSF), polyethersulfone (PES), polyphenylene sulfide (PPS), polyetheretherketone (PEEK), polyetherimide (PEI), benzocyclobutene (BCB), a fluororesin, and a liquid crystal polymer (LCP). Among them, polyimide (PI), an epoxy resin, a urethane acrylate resin, or benzocyclobutene (BCB) is preferably contained. As the resin material, one type can be used alone or two or more types can be used in combination. According to some embodiments of the present disclosure, the resin material contains polyimide (PI). By containing polyimide (PI), the desired effect of the present disclosure can be efficiently exhibited. With such an embodiment, the desired effect of the present disclosure can be efficiently exhibited.

The polishing target preferably further contains a metal material in addition to the resin material. The type of the metal material is not particularly limited, and examples thereof include magnesium (Mg), aluminum (Al), titanium (Ti), chromium (Cr), manganese (Mn), iron (Fe), cobalt (Co), nickel (Ni), copper (Cu), zinc (Zn), zirconium (Zr), gold (Au), silver (Ag), platinum (Pt), iridium (Ir), bismuth (Bi), niobium (Nb), molybdenum (Mo), tin (Sn), tungsten (W), lead (Pb), and the like. Among them, it is preferable to contain a transition metal (particularly, an element of group 6, 9, or 11 of the periodic table), an element of group 13 of the periodic table, or an element of group 14 of the periodic table, and it is more preferable to contain an element of group 11 of the periodic table or group 14 of the periodic table. The element of group 11 of the periodic table is further preferably copper (Cu), and the element of group 14 of the periodic table is further preferably tin (Sn). The metal material may be simple substances of various metal elements, an alloy containing these elements and one or more other elements, or the like. As the metal material, one type can be used alone or two or more types can be used in combination.

### Polishing Composition

### Alumina Particles

The polishing composition according to the present embodiment contains alumina particles as abrasive grains. The abrasive grains mechanically polish the polishing target and improve the polishing removal rate. Since alumina particles have a sufficient hardness, the effect of improving the polishing removal rate for the resin material is particularly high.

In the alumina particles, the degree of deformity N represented by the above formula (1) satisfies the relationship of the above formula (2). The degree of deformity N represented by the above formula (1) is a parameter indicating the degree of irregularity of the outer shape of a particle with respect to a true sphere having a similar particle size, and the larger the degree of deformity N is than 1, the larger the degree of irregularity of the particle shape is. When the degree of deformity N is 1, the particle is a true sphere. Since the alumina particles according to the present embodiment have a degree of deformity N in the range of 2 or more and 6 or less, the degree of irregularity of the particle shape is large.

Further, in the alumina particles, the degree of distortion S represented by the above formula (3) satisfies the relationship of the above formula (4). The degree of distortion S represented by the above formula (3) is a parameter indicating the symmetry (degree of bias) of the particle size distribution in the alumina particles. Here, the particle size distribution is a graph in which the X-axis shows a particle size (μm) expressed by a common logarithm with base 10 and the Y-axis shows a volume frequency (%). The fact that the degree of distortion S is less than 1 (S<1) means that the particle size distribution of the alumina particles is biased toward the large particle size side, that is, the number of alumina particles having a large particle size is relatively large. On the other hand, the fact that the degree of distortion S exceeds 1 (1<S) means that the particle size distribution of the alumina particles is biased toward the small particle size side, that is, the number of alumina particles having a small particle size is relatively large. The fact that the degree of distortion S is 1 (S=1) indicates that the particle size distribution of the alumina particles is symmetric, that is, the particle size distribution of the alumina particles is log-normal distribution. The alumina particles according to the present embodiment have a degree of distortion S in the range of 0.50 or more and 0.80 or less, and therefore have a particle size distribution biased toward the large particle size side (a relatively large number of particles having a large particle size).

Normally, it is known that abrasive grains having a relatively large size have a high polishing removal rate, and it is known that the polishing removal rate increases as the shape irregularity and aspect ratio of the abrasive grains increase. On the other hand, abrasive grains having a relatively large size and abrasive grains having a high shape irregularity and a high aspect ratio increase defects such as scratches on the surface of the polishing target after polishing. On the other hand, abrasive grains having a relatively small size tend to improve defects such as scratches on the surface of the polishing target after polishing although the polishing removal rate decreases. In addition, it is known that spherical particles have a relatively low polishing removal rate as compared with deformed particles, but reduce defects such as scratches on the surface of the polishing target after polishing. As described above, there is a trade-off relationship between the improvement in the polishing removal rate and the occurrence of defects such as scratches. However, as a result of repeated studies, the inventors of the present disclosure have found that a polishing composition containing alumina particles in which the degree of deformity N represented by the above formula (1) satisfies the relationship of the above formula (2) and the degree of distortion S represented by the above formula (3) satisfies the relationship of the above formula (4) can reduce defects on the surface of a resin material after polishing while maintaining a high polishing removal rate in polishing the polishing target containing a resin material.

### Degree of Deformity N

When the degree of deformity N of the alumina particles is less than 2, the polishing removal rate for the resin material (polishing target) decreases. When the degree of deformity N of the alumina particles exceeds 6, scratches on the surface of the polished resin material (polishing target) deteriorate. The degree of deformity N of the alumina particles is preferably 2.1 or more and 5.0 or less, and more preferably 2.2 or more and 4.0 or less.

The BET specific surface area SA of the alumina particles used in calculating the degree of deformity N is a specific surface area measured based on JIS Z 8830:2013. More specifically, it can be measured by the method described in examples.

In addition, the theoretical specific surface area SA′ of the alumina particles is a value calculated by formula (5) below using the value of D₅₀ used for calculating the degree of distortion S.

$$\begin{matrix}[ Math . 3 ] & \\ Theoretical specific surface area {SA}^{′} = \frac{6}{ρ \times {D}_{50}} & ( 5 )\end{matrix}$$

In the above formula (5), ρ is the density of alumina particles, and a value of 3.95 g/cm³ is used.

### Degree of Distortion S

When the degree of distortion S of the alumina particles is less than 0.50, scratches on the surface of the polished resin material (polishing target) deteriorate. When the degree of distortion S of the alumina particles exceeds 0.80, the polishing removal rate for the resin material (polishing target) decreases. The degree of distortion S of the alumina particles is preferably 0.55 or more and 0.78 or less, and more preferably 0.60 or more and 0.75 or less.

D₂, D₅₀, and D₉₈ of the alumina particles used in calculating the degree of distortion S can be determined by a dynamic light scattering method, a laser diffraction method, a laser scattering method, a pore electric resistance method, or the like. In the present specification, in a volume-based particle size distribution measured using a laser diffraction particle size distribution measuring apparatus, values obtained from a particle size at which a cumulative frequency from a small particle size side is 2%, a particle size at which a cumulative frequency from a small particle size side is 50%, and a particle size at which a cumulative frequency from a small particle size side is 98% are respectively adopted. More specifically, it can be measured by the method described in examples.

The shape of the alumina particles is not particularly limited as long as the degree of deformity N and the degree of distortion S satisfy the relationships of the above formulae (2) and (4). Examples of the shape of the alumina particles include various shapes such as a polygonal columnar shape such as a triangular prism or a quadrangular prism, a cylindrical shape, a straw rice bag shape in which a central portion of a cylinder is bulged more than the end portions, a doughnut shape in which a central portion of a disk is perforated, a plate shape, a so-called cocoon shape having a constriction at a central portion, a so-called associative spherical shape in which a plurality of particles are integrated, a so-called kompeito shape having a plurality of protrusions on a surface, a rugby ball shape, a conical shape, a truncated conical shape, a pyramid shape, a truncated pyramid shape, a hemispherical shape, a needle shape, and an irregular shape.

The D₅₀ of the alumina particles is not particularly limited as long as the degree of deformity N and the degree of distortion S satisfy the relationships of the above formulae (2) and (4). As an example, the D₅₀ of the alumina particles is preferably 2.0 μm or less, more preferably 1.5 μm or less, still more preferably 1.0 μm or less, particularly preferably 0.8 μm or less, and most preferably 0.4 μm or less. The D₅₀ of the alumina particles is preferably 0.01 μm or more, more preferably 0.02 μm or more, still more preferably 0.05 μm or more, particularly preferably 0.1 μm or more, and most preferably 0.2 μm or more. When the D₅₀ of the alumina particles is within the above range, it is possible to achieve both an improvement in the polishing removal rate for the resin material and a reduction in scratches on the surface of the resin material after polishing in a more balanced manner. A preferred example of the D₅₀ of the alumina particles is preferably 0.01 μm or more and 2.0 μm or less, more preferably 0.02 μm or more and 1.5 μm or less, further preferably 0.05 μm or more and 1.0 μm or less, particularly preferably 0.1 μm or more and 0.8 μm or less, and most preferably 0.2 μm or more and 0.4 μm or less.

### αTransformation Rate

The alumina particles preferably contain an α phase which is a preferred crystal structure as a polishing abrasive grain, or a crystal phase in a transition state in a process of becoming an α phase such as a θ phase, a δ phase, or a γ phase. It is more preferable to contain an α phase or a θ phase, and it is still more preferable to contain an α phase. In addition, it is considered that there is an optimum range for the α phase depending on the degree of α phase transformation.

In general, the crystal structure of the α phase is considered to be the hardest, but it is presumed that when sintering is sufficiently performed at a high temperature for α phase transformation, the particle shape changes to round and the polishing performance deteriorates. As a value representing the degree of α phase contained in the alumina particles, the α transformation rate is used as a reference. The lower limit of the α transformation rate is preferably 50% or more. The lower limit of the α transformation rate is more preferably 60% or more, still more preferably 70% or more, even more preferably 80% or more, and particularly preferably 90% or more. The upper limit of the α transformation rate is preferably 100% or less. The upper limit of the α transformation rate is more preferably 98% or less. That is, the α transformation rate of the alumina particles is preferably 50% or more and 100% or less, more preferably 60% or more and 98% or less, and still more preferably 80% or more and 98% or less.

By setting the α transformation rate to the above preferred range, it is expected that the polishing power is improved, that is, the polishing removal rate for the resin material is further improved. The α transformation rate of the alumina particles can be calculated from the integrated intensity ratio of a peak at 2θ=43°±2° corresponding to the (113) plane obtained by X-ray diffraction measurement using a Cu-Kα ray between a reference substance and a measurement sample. A more specific method is described in examples.

### Concentration (Content)

The concentration (content) of the alumina particles in the polishing composition is not particularly limited, but is preferably 0.01 mass % or more, more preferably 0.1 mass % or more, still more preferably 0.5 mass % or more, even more preferably 1 mass % or more, and particularly preferably 1.5 mass % or more with respect to the total mass of the polishing composition. As the concentration of the alumina particles increases, the polishing removal rate is further improved. In addition, the concentration (content) of the alumina particles is preferably 25 mass % or less, more preferably 15 mass % or less, still more preferably 10 mass % or less, even more preferably less than 9 mass %, and particularly preferably 8 mass % or less with respect to the total mass of the polishing composition. Within the above range, the polishing removal rate for the resin material can be further improved. In addition, there is also an effect that the occurrence of defects such as scratches on the surface of the resin material after polishing is further reduced. A preferred example of the concentration (content) of the alumina particles is 0.01 mass % or more and 25 mass % or less, more preferably 0.1 mass % or more and 15 mass % or less, still more preferably 0.5 mass % or more and 10 mass % or less, even more preferably 1 mass % or more and less than 9 mass %, and particularly preferably 1.5 mass % or more and 8 mass % or less with respect to the total mass of the polishing composition.

A method for producing alumina particles in which the degree of deformity N and the degree of distortion S satisfy the above formulae (2) and (4) is not particularly limited, and examples thereof include a method in which a powder obtained by firing a starting material such as an aluminum oxide precursor powder is appropriately pulverized and/or classified.

The aluminum oxide precursor powder may be an aluminum hydroxide powder or an aluminum oxide powder containing a transitional aluminum oxide phase. The aluminum hydroxide powder may be gibbsite, boehmite, pseudo-boehmite, diaspore, or any combination thereof. The aluminum oxide precursor powder can contain gamma (γ), eta (η), theta (θ), chi (χ), kappa (κ), and/or delta (δ) phase aluminum oxide.

Aluminum oxide (alumina) can be formed by firing the aluminum oxide precursor powder. The firing method is not particularly limited, and examples thereof include a method using a rotary kiln, a tunnel kiln, an electric furnace, a muffle furnace, an elevator kiln, or a pusher kiln. The firing temperature may be 700° C. or higher and 1,600° C. or lower, and the firing time may be 1 hour or more and 48 hours or less. This makes it possible to obtain α-alumina having a suitable α transformation rate. As the firing temperature is higher, the specific surface area tends to be smaller.

By appropriately pulverizing and classifying the fired alumina powder, alumina having a desired particle size distribution can be obtained. Pulverization and classification can be performed in a wet process or a dry process.

Examples of the pulverization method include a method using a pulverizer. As the pulverizer, for example, a known apparatus such as a ball mill, a bead mill, a planetary mill, a vibration mill, a colloid mill, a conical mill, a disk mill, an edge mill, a flour mill, a hammer mill, a mortar, a pellet mill, a VSI mill, a wheelie mill, a roller mill, a jet mill, a homomixer, a high-pressure homogenizer, or an ultrasonic apparatus can be used. In each apparatus, for example, alumina having a desired particle size distribution can be obtained by changing pulverization conditions such as a pulverization time.

As an example of the classification method, for example, various methods including filtering (filtration), a sieving method, an air flow classification method, an elutriation classification method, a weight classification method, an inertial classification method, a centrifugal classification method, and the like can be used. Examples of the filtering include coarse filtration, microfiltration, ultrafiltration, reverse osmosis, and the like and various filtration techniques can be used. Examples of the filter used for filtering include a mesh filter, a depth filter, a membrane filter, and the like. In the filtering, the particle size distribution of the powder can be controlled by adjusting the filtration time, the filtration speed, the filtration accuracy, and the like. For example, the filtration accuracy may be 0.1 μm or more and 300 μm or less.

By appropriately selecting and/or combining one or more of the firing method, the pulverization method, and the classification and filtering method described above and controlling the respective conditions, it is possible to obtain alumina particles in which the degree of deformity N and the degree of distortion S satisfy the relationships of the above formulae (2) and (4).

As the alumina particles, a commercially available product may be used. As the alumina particles, one type can be used alone or two or more types can be used in combination.

### Water

The polishing composition according to the present disclosure contains water. The water disperses or dissolves each component. From the viewpoint of preventing the effect of impurities on other components of the polishing composition, it is preferable to use water of as high purity as possible. Specifically, pure water, ultrapure water, or distilled water from which impurity ions are removed with an ion exchange resin and then foreign substances are removed through a filter is preferable. In addition, for the purpose of controlling the dispersibility or the like of other components in the polishing composition, an organic solvent or the like as a dispersing medium may be further contained.

### Other Components

The polishing composition according to the present disclosure may further contain known components such as a pH adjusting agent, a surfactant, a dispersant, a thickener (viscosity modifier), a surface protecting agent, a wetting agent, an oxidizing agent, a water-soluble polymer, a salt, an anticorrosive agent, an antiseptic agent, and an antifungal agent as long as the effects of the present disclosure are not impaired. The content of these other components may be appropriately set according to the purpose of addition. Hereinafter, a pH adjusting agent, a surfactant, a dispersant, a thickener (viscosity modifier), an oxidizing agent, an anticorrosive agent, an antiseptic agent, and an antifungal agent will be described. The chelating agent will also be described.

### pH Adjusting Agent

The polishing composition according to some embodiments of the present disclosure may further contain a pH adjusting agent. The pH adjusting agent can contribute to the adjustment of the pH of the polishing composition by selecting the type and addition amount thereof.

The pH adjusting agent is not particularly limited as long as it is a compound having a pH adjusting function, and a known compound can be used. Examples of the compound that can be used as the pH adjusting agent include an acid, an alkali, and the like.

As the acid, either an inorganic acid or an organic acid may be used. The inorganic acid is not particularly limited, and examples thereof include sulfuric acid, nitric acid, boric acid, carbonic acid, hypophosphorous acid, phosphorous acid, phosphoric acid, and the like. The organic acid is not particularly limited, and examples thereof include carboxylic acids such as formic acid, acetic acid, propionic acid, butyric acid, valeric acid, 2-methylbutyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, benzoic acid, glycolic acid, salicylic acid, glyceric acid, oxalic acid, malonic acid, succinic acid, glutaric acid, adipic acid, pimelic acid, maleic acid, phthalic acid, malic acid, tartaric acid, citric acid, and lactic acid, and methanesulfonic acid, ethanesulfonic acid, isethionic acid, and the like. Among them, an organic acid is preferable, and malic acid, citric acid, and maleic acid are more preferable. When an inorganic acid is used, nitric acid, sulfuric acid, or phosphoric acid is preferable.

The alkali is not particularly limited, and examples thereof include a hydroxide of an alkali metal, a salt of an alkali metal, a hydroxide of an alkaline earth metal, a salt of an alkaline earth metal, a quaternary ammonium salt, ammonia, and the like.

Specific examples of the alkali metal include potassium, sodium, and the like. Specific examples of the alkaline earth metal include calcium, strontium, and the like. Specific examples of the salt include a carbonate, a hydrogen carbonate, a sulfate, an acetate, and the like. Specific examples of the quaternary ammonium salt include a salt containing a tetramethylammonium cation, a tetraethylammonium cation, a tetrabutylammonium cation, or the like, and a hydroxide of such a quaternary ammonium cation. Among them, potassium hydroxide or ammonia is preferable as the alkali.

As the pH adjusting agent, one type can be used alone or two or more types can be used in combination.

The pH of the polishing composition according to some embodiments of the present disclosure is not particularly limited, but is preferably alkaline from the viewpoint of a polishing removal rate, and is preferably 8 or more. The pH is more preferably 9 or more, still more preferably 10 or more, and particularly preferably 11 or more. In addition, the pH is preferably 14 or less, more preferably 13 or less, and still more preferably 12 or less from the viewpoint of further improving the polishing removal rate for the resin material and reducing scratches. As an example, the pH of the polishing composition can be set in the range of 8 or more and 14 or less, and is preferably in the range of 9 or more and 13 or less, and more preferably 10 or more and 12 or less. Within the above range, there is an effect that both an improvement in the polishing removal rate for the resin material and a reduction in scratches can be achieved in a more balanced manner. The content of the pH adjusting agent is not particularly limited, and is preferably such an amount that the pH value can be adjusted to a value within the above preferred range.

### Surfactant

The polishing composition according to some embodiments of the present disclosure may contain a surfactant. The surfactant that can be contained in the polishing composition of the present disclosure is at least one type selected from the group consisting of an anionic surfactant, a cationic surfactant, an amphoteric surfactant, and a nonionic surfactant. Among them, a nonionic surfactant is preferable as the surfactant contained in the polishing composition. As the surfactant, one type can be used alone or two or more types can be used in combination.

Examples of the anionic surfactant include a polyoxyethylene alkyl ether acetic acid, a polyoxyethylene alkyl sulfuric acid ester, an alkyl sulfuric acid ester, a polyoxyethylene alkyl ether sulfuric acid, an alkyl ether sulfuric acid, an alkyl benzene sulfonic acid, an alkyl phosphoric acid ester, a polyoxyethylene alkyl phosphoric acid ester, a polyoxyethylene sulfosuccinic acid, an alkyl sulfosuccinic acid, an alkyl naphthalene sulfonic acid, an alkyl diphenyl ether disulfonic acid, salts thereof, and the like.

Examples of the cationic surfactant include an alkyltrimethylammonium salt, an alkyldimethylammonium salt, an alkylbenzyldimethylammonium salt, an alkylamine salt, and the like.

Examples of the amphoteric surfactant include an alkyl betaine and an alkylamine oxide.

Examples of the nonionic surfactant include a polyoxyalkylene alkyl ether such as a polyoxyethylene alkyl ether, a sorbitan fatty acid ester, a glycerin fatty acid ester, a polyoxyethylene fatty acid ester, a polyoxyethylene alkylamine, an alkyl alkanolamide, and the like.

When the polishing composition contains a surfactant, the content of the surfactant is preferably 0.01 mass % or more, and more preferably 0.1 mass % or more with respect to the total mass of the polishing composition. In addition, the content of the surfactant in the polishing composition is preferably 3.0 mass % or less, and more preferably 2.0 mass % or less with respect to the total mass of the polishing composition. When the content of the surfactant is within the above range, the uniformity of polishing of the polishing target is further improved.

### Dispersant/Thickener (Viscosity Modifier)

The polishing composition according to some embodiments of the present disclosure may contain a dispersant or a thickener (viscosity modifier). The dispersant or the thickener plays a role of uniformly dispersing the abrasive grains (alumina particles) in a liquid, thereby enabling the abrasive grains to efficiently act on the polishing target. In addition, due to the presence of the dispersant or the thickener between the abrasive grains, an action of preventing caking of the abrasive grains can also be expected, and accordingly, occurrence of scratches caused by aggregated abrasive grains is prevented.

Specific examples of the dispersant include, as a colloidal substance as a substance containing fine particles, colloidal alumina, colloidal silica, colloidal zirconia, colloidal titania, alumina sol, silica sol, zirconia sol, titania sol, fumed alumina, fumed silica, fumed zirconia, fumed titania, and the like. In addition, sodium phosphate, sodium hexametaphosphate, sodium pyrophosphate, or the like, which is generally used as a dispersant, may be used.

Specific examples of the thickener include glycols such as a propylene glycol polymer, an ethylene glycol polymer, and the like, and a polymer compound. More specific examples of the glycols include propylene glycol, ethylene glycol, dipropylene glycol, polypropylene glycol, diethylene glycol, polyethylene glycol, and the like. Examples of the polymer compound include sodium polyacrylate, polyvinyl alcohol, hydroxyethyl cellulose, and the like.

### Oxidizing Agent

When the polishing target contains a metal material, the polishing composition according to some embodiments of the present disclosure may contain an oxidizing agent. The oxidizing agent has a function of oxidizing and hardening the surface of the metal material and preventing the occurrence of defects such as scratches. Specific examples of the oxidizing agent include a peroxide such as hydrogen peroxide, a nitrate, an iodate, a periodate, a hypochlorite, a chlorite, a chlorate, a perchlorate, a persulfate, a dichromate, a permanganate, ozone water, a silver (II) salt, an iron (III) salt, and the like. As the oxidizing agent, one type can be used alone or two or more types can be used in combination. As the oxidizing agent, a commercially available product or a synthetic product may be used.

### Anticorrosive Agent

When the polishing target contains a metal material, the polishing composition according to some embodiments of the present disclosure may contain an anticorrosive agent. The anticorrosive agent has a function of preventing excessive dissolution of the metal material. Examples of the anticorrosive agent include a heterocyclic compound. The number of heterocycles in the heterocyclic compound is not particularly limited. The heterocyclic compound may be a monocyclic compound or a polycyclic compound having a fused ring. As the anticorrosive agent, one type can be used alone or two or more types can be used in combination. As the anticorrosive agent, a commercially available product or a synthetic product may be used.

Specific examples of the heterocyclic compound that can be used as the anticorrosive agent include nitrogen-containing heterocyclic compounds such as a pyrrole compound, a pyrazole compound, an imidazole compound, a triazole compound, a tetrazole compound, a pyridine compound, a pyrazine compound, a pyridazine compound, a pyrindine compound, an indolizine compound, an indole compound, an isoindole compound, an indazole compound, a purine compound, a quinolizine compound, a quinoline compound, an isoquinoline compound, a naphthyridine compound, a phthalazine compound, a quinoxaline compound, a quinazoline compound, a cinnoline compound, a buteridine compound, a thiazole compound, an isothiazole compound, an oxazole compound, an isoxazole compound, a furazan compound, and the like.

### Antifungal Agent, Antiseptic Agent

The polishing composition according to some embodiments of the present disclosure may contain an antifungal agent or an antiseptic agent. Specific examples of the antifungal agent and the antiseptic agent include isothiazoline-based antiseptic agents (for example, 2-methyl-4-isothiazolin-3-one, 5-chloro-2-methyl-4-isothiazolin-3-one), a paraoxybenzoic acid ester, phenoxyethanol, and the like. As the antifungal agent and the antiseptic agent, one type can be used alone or two or more types can be used in combination.

### Chelating Agent

When the polishing target contains a metal material, it is preferable that the polishing composition according to some embodiments of the present disclosure is substantially free of a chelating agent. This makes it possible to prevent an increase in scratching or dishing on the surface of the metal material due to a chelating agent in the polishing composition. Here, the clause “the polishing composition is substantially free of a chelating agent” means that a chelating agent is not added to the polishing composition at least intentionally, and includes a form in which a chelating agent is contained in an amount of 0.1 mass % or less in the polishing composition in addition to a concept in which a chelating agent is not contained in the polishing composition at all. The concentration (content) of the chelating agent, with respect to the total mass of the polishing composition, is more preferably 0.05 mass % or less, still more preferably 0.01 mass % or less, and particularly preferably 0 mass %, that is, no chelating agent is contained. Examples of the chelating agent include an aminocarboxylic acid-based chelating agent and an organic phosphonic acid-based chelating agent.

### Polishing Removal Rate

The polishing composition according to some embodiments of the present disclosure can improve the polishing removal rate for the resin material. As an example, the polishing removal rate for the resin material is preferably 2.0 μm/min or more, more preferably 2.3 μm/min or more, and still more preferably 2.5 μm/min or more. The polishing removal rate is obtained by the method described in examples.

### Method for Producing Polishing Composition

In the polishing composition according to some embodiments of the present disclosure, a method for producing (method for preparing) the polishing composition is not particularly limited, and for example, a production method including stirring and mixing alumina particles, water, and other components as necessary can be appropriately adopted. The alumina particles, water, and other components are the same as those described above, and thus the description thereof is omitted here.

In the polishing composition, the temperature at the time of mixing the respective components is not particularly limited, but is preferably 10° C. or higher and 40° C. or lower, and heating may be performed in order to increase the rate of dissolution. The mixing time is also not particularly limited.

### Polishing Method

A second embodiment of the present disclosure relates to a polishing method including polishing a polishing target containing a resin material using the above-described polishing composition. Preferred examples of the polishing target according to the present embodiment are the same as those mentioned in the description of [Polishing target].

When the polishing target is polished using the polishing composition, the polishing can be performed using an apparatus and conditions used for normal polishing. Examples of a general polishing apparatus include a single-side polishing apparatus and a double-side polishing apparatus. In a single-side polishing apparatus, generally, a polishing target is held using a holding tool called a carrier, and while the polishing composition is supplied from above, a platen having a polishing pad attached thereto is pressed against one surface of the polishing target, and the surface of the polishing target is polished by rotating the platen. In a double-side polishing apparatus, generally, a polishing target is held using a holding tool called a carrier, and while the polishing composition is supplied from above, platens having a polishing pad attached thereto are pressed against opposing surfaces of the polishing target, and both surfaces of the polishing target are polished by rotating the platens in a relative direction. At this time, polishing is performed by a physical action caused by friction between the polishing pad and the polishing composition, and the polishing target, and a chemical action caused by the polishing composition to the polishing target. As the polishing pad, a porous body such as a nonwoven fabric, polyurethane, or suede can be used without particular limitation. The polishing pad is preferably processed such that a polishing liquid is accumulated.

Examples of the polishing conditions include a polishing load, a platen rotation speed, a carrier rotation speed, a flow rate of the polishing composition, a polishing time, and the like. These polishing conditions are not particularly limited, but for example, the polishing load is preferably 0.1 psi (0.69 kPa) or more and 10 psi (69 kPa) or less, and more preferably 0.5 psi (3.5 kPa) or more and 8.0 psi (55 kPa) or less per unit area of the polishing target. In general, as the load increases, the frictional force by the abrasive grains increases, and the mechanical processing force is improved, so that the polishing removal rate increases. Within this range, a sufficient polishing removal rate is exhibited, and it is possible to prevent breakage of the polishing target due to a load and occurrence of defects such as scratches on the surface. The platen rotation speed and the carrier rotation speed are preferably 10 rpm (0.17 s⁻¹) or more and 500 rpm (8.3 s⁻¹) or less. The supply amount of the polishing composition may be a supply amount (flow rate) at which the entire polishing target is covered, and may be adjusted according to conditions such as the size of the polishing target. The method of supplying the polishing composition to the polishing pad is not particularly limited, and for example, a method of continuously supplying the polishing composition by a pump or the like is adopted. In addition, the processing time is not particularly limited as long as a desired processing result is obtained, but it is preferable to set the processing time to a shorter time due to a high polishing removal rate.

In addition, a third embodiment of the present disclosure relates to a method for producing a polished polishing target including polishing a polishing target by the above-described polishing method. Preferred examples of the polishing target according to the present embodiment are the same as those mentioned in the description of [Polishing target]. As a preferred example, there is a method for producing an electronic circuit board including polishing a polishing target containing a resin material by the above-described polishing method.

Although the embodiments of the present disclosure have been described in detail, this is illustrative and exemplary and not restrictive, and it is clear that the scope of the present disclosure should be interpreted by the appended claims.

The present disclosure includes the following clauses:
Clause 1. A polishing composition used for polishing a polishing target containing a resin material, the polishing composition containing:
   water; and
   alumina particles;
   in which, in the alumina particles, when
   a particle size at which a cumulative frequency from a small particle size side is 2% in a volume-based particle size distribution is denoted by D₂,
   a particle size at which a cumulative frequency from a small particle size side is 50% in a volume-based particle size distribution is denoted by D₅₀,
   a particle size at which a cumulative frequency from a small particle size side is 98% in a volume-based particle size distribution is denoted by D₉₈,
   a BET specific surface area is denoted by SA, and
   a theoretical specific surface area calculated from the D₅₀ is denoted by SA′,
   a degree of deformity N represented by formula (1) below satisfies a relationship of formula (2) below, and a degree of distortion S represented by formula (3) below satisfies a relationship of formula (4) below.

$$\begin{matrix}[ Math . 4 ] & \\ Degree of deformity N = \frac{SA}{{SA}^{′}} & ( 1 )\end{matrix}$$

$$2 \leq N \leq 6 \qquad ( 2 )$$

$$Degree of distortion S = \frac{( {D}_{50} / {D}_{2} )}{( {D}_{98} / {D}_{50} )} \qquad ( 3 )$$

$$0.5 \leq S \leq 0.80 \qquad ( 4 )$$

Clause 2. The polishing composition according to Clause 1, in which D₅₀ of the alumina particles is 0.2 μm or more and 0.4 μm or less.
Clause 3. The polishing composition according to Clause 1 or 2, in which an α transformation rate of the alumina particles is 80% or more and 98% or less.
Clause 4. The polishing composition according to any one of Clauses 1 to 3, in which the resin material contains polyimide.
Clause 5. The polishing composition according to any one of Clauses 1 to 4, in which the polishing target further contains a metal material.
Clause 6. The polishing composition according to any one of Clauses 1 to 5, in which the polishing composition is substantially free of a chelating agent.
Clause 7. A polishing method including polishing a polishing target containing a resin material using the polishing composition according to any one of Clauses 1 to 6.

### EXAMPLES

Examples of the present disclosure will be described. However, the technical scope of the present disclosure is not limited only to the following examples. Unless otherwise specified, “%” and “part(s)” mean “mass %” and “part(s) by mass”, respectively.

### Preparation of Polishing Compositions of Examples 1 and 2 and Comparative Examples 1 to 11

Alumina particles as abrasive grains and pure water were mixed, and then pulverization and classification were appropriately performed. Thereafter, potassium hydroxide was used as a pH adjusting agent, and a polishing composition having a pH value of 11.0 was prepared (mixing temperature: about 25°° C., mixing time: about 30 minutes). The concentration of the alumina particles in the polishing composition was 3.0 mass %.

With respect to the polishing composition obtained above, the physical properties of the alumina particles, the polishing removal rate for polyimide, and scratches on the polyimide surface were evaluated.

### Evaluation

### D₂, D₅₀, and D₉₈ of Alumina Particles

The alumina particles were measured using a laser diffraction particle size distribution measuring apparatus (Microtrac particle size distribution measuring apparatus MT3300EX II manufactured by Microtrac Bell Co., Ltd.) to obtain a volume-based particle size distribution. In the obtained particle size distribution, a particle size at which a cumulative frequency from a small particle size side was 2% was defined as D₂ of alumina particles, a particle size at which a cumulative frequency from a small particle size side was 50% was defined as D₅₀ of alumina particles, and a particle size at which a cumulative frequency from a small particle size side was 98% was defined as D₉₈ of alumina particles.

### BET Specific Surface Area of Alumina Particles

The BET specific surface area SA of the alumina particles was measured using a fully automatic specific surface area measuring apparatus (Macsorb (registered trademark) HM model-1201) manufactured by Mountech Co., Ltd.

### Theoretical Specific Surface Area SA′ of Alumina Particles

The theoretical specific surface area SA′ of the alumina particles was calculated by the following formula (5) using the value of D₅₀ measured above.

$$\begin{matrix}[ Math . 5 ] & \\ Theoretical specific surface area {SA}^{′} = \frac{6}{ρ \times {D}_{50}} & ( 5 )\end{matrix}$$

In formula (5), ρ is the density of the alumina particles, and a value of 3.95 g/cm³ was used.

From D₂, D₅₀, D₉₈, SA, and SA′ obtained above, the degree of deformity N and the degree of distortion S were calculated according to the following formulae (1) and (3).

$$\begin{matrix}[ Math . 6 ] & \\ Degree of deformity N = \frac{SA}{{SA}^{′}} & ( 1 )\end{matrix}$$

$$Degree of distortion S = \frac{( {D}_{50} / {D}_{2} )}{( {D}_{98} / {D}_{50} )} \qquad ( 3 )$$

### α Transformation Rate of Alumina Particles

The α transformation rate of the alumina particles was calculated using an X-ray diffractometer (Ultima-IV, manufactured by Rigaku Corporation). As a reference substance, commercially available α-alumina single crystal particles (α transformation rate: 100%) in which the firing temperature was sufficiently high and α transformation sufficiently proceeded were used. The α transformation rate of the alumina particles (abrasive grains) as the measurement sample was calculated from the integrated intensity ratio of the peak at 2θ=43°±2° corresponding to the (113) plane measured using a Cu-Kα ray for the alumina particles (abrasive grains) as the reference substance and the measurement sample, (see the following formula (6)).

$$\begin{matrix}[ Math . 7 ] & \\ α Transformation rate ( \% ) = \frac{\begin{matrix}Integrated intensity of peak at 2 θ = \\ 43 ° \pm 2 ° ( measurement sample )\end{matrix}}{\begin{matrix}Integrated intensity of peak at 2 θ = \\ 43 ° \pm 2 ° ( reference substance )\end{matrix}} \times 100 & ( 6 )\end{matrix}$$

### Evaluation of Polishing Removal Rate and Scratches

A polyimide (PI) substrate was prepared as a polishing target, and the polishing target was polished using each polishing composition by the following polishing apparatus and polishing conditions. With respect to the polishing target after polishing, the polishing removal rate for polyimide was evaluated according to the following (Evaluation method for polishing removal rate), and scratches on the surface of the polyimide substrate after polishing were evaluated according to the following (Evaluation method for scratches).

### Polishing Target

Polyimide substrate: size: 30 mm×30 mm (product name: PIMEL BM302H, manufactured by Asahi Kasei Corporation)

### Polishing Apparatus and Polishing Conditions

Polishing apparatus: small tabletop polishing machine (EJ 380IN, manufactured by ENGIS JAPAN Corporation)
Platen diameter: 380 [mm]
Polishing pad: nonwoven fabric pad (SUBA 800 manufactured by NITTA DuPont Incorporated)
Platen rotation speed: 340 [rpm]
Head (carrier) rotation speed: 50 [rpm]
Polishing pressure: 3.0 [psi] (210 [g/cm²], 207 kPa)
Flow rate of polishing composition: 80 [ml/min]
Polishing time: 1 [min]

### Evaluation Method for Polishing Removal Rate

1. The mass of the polishing target before and after polishing was measured using an analytical balance XS205 (manufactured by Mettler Toledo Co., Ltd.), and the amount of change in mass ΔM [kg] of the polishing target before and after polishing was calculated from the difference therebetween.
2. The amount of change in volume ΔV [m³] of the polishing target before and after polishing was calculated by dividing the amount of change in mass ΔM [kg] of the polishing target before and after polishing by the specific gravity of the polishing target (specific gravity of polishing target).
3. The amount of change in thickness Δd [m] of the polishing target before and after polishing was calculated by dividing the amount of change in volume ΔV [m³] of the polishing target before and after polishing by the area s [m²] of the polished surface of the polishing target.
4. The unit was further converted to [μm/min] by dividing the amount of change in thickness Δd [m] of the polishing target before and after polishing by the polishing time t [min]. This value was defined as a polishing removal rate v [μm/min].

### Evaluation Method for Scratches

The surface of the polyimide substrate after polishing was visually observed, and scratches were evaluated according to the following evaluation criteria.
A: Scratches cannot be visually observed under fluorescent light.
B: Scratches can be visually observed under fluorescent light.

The results are shown in Table 1 below.

TABLE 1

| | Abrasive grains (alumina particles) | | | | | | | | | Evaluation results | |
|---|---|---|---|---|---|---|---|---|---|---|---|
| | | | | | | | | | α | Polishing | |
| | | Degree of deformity N | | | Degree of distortion S | | | | Transformation | removal | |
| | | SA | SA′ | N | D₉₈ | D₅₀ | D₂ | S | rate | rate | |
| | No. | [m²/g] | [m²/g] | value | [μm] | [μm] | [μm] | value | (%) | [μm/min] | Scratches |
| Comparative | A | 13.6 | 2.2 | 6.2 | 2.5 | 0.69 | 0.24 | 0.77 | 98 | 5.5 | B |
| Example 1 | | | | | | | | | | | |
| Example 1 | B | 15.0 | 4.7 | 3.2 | 1.4 | 0.32 | 0.11 | 0.68 | 98 | 2.6 | A |
| Example 2 | C | 16.1 | 6.2 | 2.6 | 0.9 | 0.24 | 0.09 | 0.70 | 98 | 2.1 | A |
| Comparative | D | 18.3 | 6.8 | 2.7 | 0.6 | 0.22 | 0.09 | 0.92 | 98 | 1.2 | A |
| Example 2 | | | | | | | | | | | |
| Comparative | E | 23.8 | 5.7 | 4.2 | 0.8 | 0.27 | 0.10 | 0.84 | 100 | 0.9 | A |
| Example 3 | | | | | | | | | | | |
| Comparative | F | 21.9 | 2.9 | 7.5 | 1.4 | 0.52 | 0.20 | 0.96 | 97 | 1.5 | B |
| Example 4 | | | | | | | | | | | |
| Comparative | G | 59.9 | 6.2 | 9.7 | 0.6 | 0.25 | 0.11 | 0.99 | 93 | 0.9 | B |
| Example 5 | | | | | | | | | | | |
| Comparative | H | 8.1 | 6.8 | 1.2 | 0.7 | 0.22 | 0.09 | 0.81 | 95 | 0.4 | A |
| Example 6 | | | | | | | | | | | |
| Comparative | I | 6.4 | 5.8 | 1.1 | 1.2 | 0.26 | 0.11 | 0.51 | 100 | 0.6 | A |
| Example 7 | | | | | | | | | | | |
| Comparative | J | 9.7 | 8.6 | 1.1 | 0.4 | 0.18 | 0.08 | 1.10 | 60 | 0.3 | A |
| Example 8 | | | | | | | | | | | |
| Comparative | K | 11.3 | 6.9 | 1.6 | 2.9 | 0.22 | 0.08 | 0.20 | 98 | 1.2 | B |
| Example 9 | | | | | | | | | | | |
| Comparative | L | 17.5 | 6.9 | 2.7 | 1.2 | 0.22 | 0.10 | 0.40 | 98 | 1.5 | B |
| Example 10 | | | | | | | | | | | |
| Comparative | M | 35.2 | 4.7 | 7.5 | 1.8 | 0.32 | 0.12 | 0.47 | 98 | 2.1 | B |
| Example 11 | | | | | | | | | | | |

As is apparent from Table 1 above, it was shown that the polishing compositions of examples are excellent in both the polishing removal rate for polyimide and the scratches on the polyimide surface after polishing. On the other hand, it was shown that the polishing compositions of comparative examples in which either one or both of the degree of deformity N and the degree of distortion S are out of the scope of the present disclosure are inferior to the polishing compositions of examples in either one or both of the polishing removal rate for polyimide and the scratches on the polyimide surface after polishing.

What is claimed is:

1. A polishing composition used for polishing a polishing target containing a resin material, the polishing composition comprising:
water; and
alumina particles;
wherein, in the alumina particles, when
a particle size at which a cumulative frequency from a small particle size side is 2% in a volume-based particle size distribution is denoted by D₂,
a particle size at which a cumulative frequency from a small particle size side is 50% in a volume-based particle size distribution is denoted by D₅₀,
a particle size at which a cumulative frequency from a small particle size side is 98% in a volume-based particle size distribution is denoted by D₉₈,
a BET specific surface area is denoted by SA, and
a theoretical specific surface area calculated from the D₅₀ is denoted by SA′,
a degree of deformity N represented by formula (1) below satisfies a relationship of formula (2) below, and a degree of distortion S represented by formula (3) below satisfies a relationship of formula (4) below.
$$\begin{matrix}[ Math . 1 ] & \\ Degree of deformity N = \frac{SA}{{SA}^{′}} & ( 1 )\end{matrix}$$
$$2 \leq N \leq 6 \qquad ( 2 )$$
$$Degree of distortion S = \frac{( {D}_{50} / {D}_{2} )}{( {D}_{98} / {D}_{50} )} \qquad ( 3 )$$
$$0.5 \leq S \leq 0.80 \qquad ( 4 )$$

2. The polishing composition according to claim 1, wherein D₅₀ of the alumina particles is 0.2 μm or more and 0.4 μm or less.

3. The polishing composition according to claim 1, wherein an α transformation rate of the alumina particles is 80% or more and 98% or less.

4. The polishing composition according to claim 1, wherein the resin material contains polyimide.

5. The polishing composition according to claim 1, wherein the polishing target further contains a metal material.

6. The polishing composition according to claim 1, wherein the polishing composition is substantially free of a chelating agent.

7. A polishing method comprising polishing a polishing target containing a resin material using the polishing composition according to claim 1.
